(19) United States
(12) Patent Application Publication
(10) Pub. No.: US 2003/0077910 A1
(43) Pub. Date: Apr. 24, 2003

(54) Etching of thin damage sensitive layers using high frequency pulsed plasma

(76) Inventors: Russell Westerman, Largo, FL (US); David J. Johnson, Palm Harbor, FL (US)

Correspondence Address: Harvey S. Kauget, Holland & Knight LLP, Suite 2300, 400 N. Ashley Street, Tampa, FL, 33602, US

(21) Appl. No.: 10/277,261

(22) Filed: Oct. 22, 2002

Related U.S. Application Data
(60) Provisional application No. 60/342,251, filed on Oct. 22, 2001.

(51) Int. Cl. C23F 1/00; H01L 21/306; C23C 16/00

(52) U.S. Cl. 438/714; 118/723 E; 156/345.47

(57) ABSTRACT

Disclosed is a system for etching thin damage sensitive layers with a plasma. The invention finds particular application for etching damage sensitive thin films such as Gallium Arsenide on Aluminum Gallium Arsenide. Damage to sensitive thin films is avoided by lowering the DC bias of the cathode. The low DC bias is achieved by increasing the frequency of the power source producing the plasma. A reduced etch rate, suitable for etching thin layers, is achieved by pulsing the RF power source between a high power and a low power at a selected duty cycle.

### RELATED APPLICATION DATA

This application claims priority from provisional application serial No. 60/342,251 filed Oct. 22, 2001 entitled “Etching of Thin, Damage Sensitive Layers Using High Frequency Pulsed Plasma,” the contents of which are fully incorporated herein by reference.

### BACKGROUND OF THE INVENTION

1. Field of the Invention

This invention relates to semiconductor manufacturing involving the etching of thin damage sensitive layers; more particularly, the present invention relates to the etching of such layers using a high frequency pulsed plasma.

2. Description of the Background Art

Materials used in semiconductor devices must have good semiconducting properties, good electron mobility, and the ability to host an insulating material. Several materials are available which have good semiconducting properties and good electron mobilities, but which are unsuitable because a good insulator can not be formed on them. Silicon, however, is widely used in semiconductor devices because silicon dioxide forms naturally on silicon and silicon dioxide is a good insulator. The disadvantage of silicon is that its mobility is not as high as other semiconductors and silicon dioxide is not the strongest insulator available. This means that compromises in speed and performance are made when silicon is used in electronic devices.

Gallium arsenide (GaAs) is also a semiconductor and is used in some electronic applications. GaAs is known as a III-V compound semiconductor material. A device made out of GaAs would be faster than the same device made out of silicon because GaAs has an electron mobility that is considerably higher than that of silicon. Due to the high electron mobility inherent to GaAs, it has become the chosen material for high speed and/or high frequency devices.

In recent years, heterojunction devices using, e.g., a GaAs/AlGaAs heterojunction structure, have been developed for application in an ultra high frequency range, such as a millimeter wave range, with improvements achieved in the performance of the heterojunction device. The heterojunction structure comprises one or more thin (less than a 1000 Angstroms) film layers of GaAs and AlGaAs.

Representative heterojunction devices include HEMTs (high electron mobility transistor), MESFETs (metal semiconductor field effect transistor), and heterojunction bipolar transistors (HBTs) using GaAs substrates and the heterojunction structure of thin films of GaAs and AlGaAs. It is important to note that these thin films within these devices are damage sensitive.

The operation of HEMT or MESFET devices is strongly related to the AlGaAs layer. The characteristics of the device are considerably dependent on small variations in the thickness and quality of the AlGaAs layer. In a HEMT device, small variations in the thickness of the AlGaAs layer considerably influence the two-dimensional electron gas concentration, consequently accurate control of the thickness of the AlGaAs layer in manufacturing the device improves the device characteristics and the yield. Similarly, in the typical fabrication of a MESFET, it is required to etch GaAs and stop on an AlGaAs layer without damaging the AlGaAs layer and to have good critical dimension (CD) control.

Although some devices were initially fabricated through wet chemical processes, more recent designs calling for tighter CD control have driven device manufacturers toward dry etch processes. However, the thin GaAs/AlGaAs layers can be damaged during plasma etching. The ion bombardment that occurs during plasma etching degrades the GaAs/AlGaAs structure and causes a corresponding reduction in device performance. It has been shown that this damage is directly related to ion bombardment during the plasma etching process.

Plasma etching GaAs selective to AlGaAs is known in the art. Early development work focused on capacitively coupled 13.56 MHz reactive ion etchers (RIE). These processes used a source of chlorine (typically BCl₃ or SiCl₄) to facilitate the formation of volatile GaClₓ and AsClₓ etch products. Selectivity to the underlying AlGaAs etch stop was achieved either through the addition of an oxygen source (forming non-volatile Al₂O₃) or a fluorine source (typically SF₆ or SiF₄) in order to form non-volatile AiF₃. While these processes are capable of producing anisotropic feature profiles with high selectivities to the underlying AlGaAs, the high ion energies associated with the self induced DC bias voltage (V_{dc}) at 13.56 MHz (typically |V_{dc}|>100 V) results in device damage and ultimately compromises device performance.

In a plasma process, ion energy at the substrate is related to the DC bias voltage (V_{dc}). The DC Bias in turn is directly related to the RF power applied to the cathode. It is important to note that a low RF power process would reduce the ion energy which in turn reduces the damage to the substrate and the associated damage sensitive layers, i.e., AlGaAs. However, the low RF power results in an isotropic etch which negates one of the advantages of dry processing. Specifically, CD control would be compromised at low RF powers. Therefore, a balance must be achieved between low RF power and anisotropy in order to successfully etch the damage sensitive structure while achieving the CD control necessary for the device.

In an effort to overcome the damage limitations of RIE based processes, device manufacturers turned to high density plasma processes such as inductively coupled plasma (ICP) and electron cyclotron resonance (ECR) reactor configurations. High density reactors allow independent control of the ion density and energy through the use of two radio frequency (RF) power sources. These configurations allow for lower ion energies (|V_{dc}|<50 V) at higher ion densities. While the lower ion energies facilitate low damage etching, the associated higher plasma densities result in GaAs etch rates in excess of 1000 Å/min making it difficult to control the etch process for thin film (<1000 Å) applications. As a result, there is poor reproducibility in the etch during the manufacturing process since the etch time of the thin film is very small, e.g., less than one minute or even less than 10 seconds. Currently, many system components, e.g., pressure control and RF power supplies with their associated matching networks, require a few seconds to stabilize the plasma, which can represent a major portion of the etch time.

Thus, improved plasma etching systems are needed that can accommodate the etching of thin damage sensitive layers, such as GaAs, with reproducible results. Current etching systems such as Reactive Ion Etching (RIE) and High Density Plasma (ICP) systems are ineffective in achieving this goal due to either their unacceptably high etch rates and/or their damaging effects to the surface of the GaAs.

### SUMMARY OF THE INVENTION

It is therefore one of the objectives of the present invention to create a plasma etching technique that is specifically adapted for use in conjunction with thin damage sensitive layers.

It is also an object of this invention to create a plasma etching technique that minimizes the self-induced DC bias voltage to thereby lessen the damage created by ion bombardment.

It is an additional object of the present invention to provide a plasma etching technique which reduces the etch rate to thereby increase the etch time to levels acceptable for manufacturing.

It is also an object of this invention to provide a plasma reactor for processing a substrate comprising a vacuum chamber; a first electrode for supporting the substrate within said vacuum chamber; a second electrode being grounded; a process gas; a pulsable radio frequency power source coupled to the first electrode and applying a voltage thereto for converting the process gas into a plasma having charged particles and activated neutral species, the pulsable radio frequency power source operating at a frequency that is greater than 13.56 MHz, generation of the plasma causing a self biasing of the first electrode, the self biasing being reduced by operating at the increased frequency of the radio frequency power source; wherein the pulsable radio frequency power source is cycled between a high power and a low power at a selected duty cycle.

It is also an object of this invention to provide a plasma reactor for processing a substrate comprising a vacuum chamber; a first electrode for supporting the substrate within said vacuum chamber; a second electrode being grounded; a process gas; and a radio frequency power source coupled to the first electrode and applying a voltage thereto for converting the process gas into a plasma having charged particles and activated neutral species, the radio frequency power source operating at a frequency that is greater than 13.56 MHz, generation of the plasma causing a self biasing of the first electrode, the self biasing being reduced by operating at the increased frequency of the power source.

It is also an object of this invention to provide a plasma reactor for processing a substrate comprising a vacuum chamber; a first electrode for supporting the substrate within said vacuum chamber; a second electrode being grounded; a process gas; a pulsable radio frequency power source coupled to the first electrode and applying a voltage thereto for converting the process gas into a plasma having charged particles and activated neutral species, the radio frequency power source operating at a frequency of 13.56 MHz; wherein the pulsable radio frequency power source is cycled between a high power and a low power at a selected duty cycle.

It is also an object of this invention to provide a plasma reactor for processing a substrate comprising a vacuum chamber; a first electrode for supporting the substrate within said vacuum chamber; a second electrode being grounded; a process gas; a first radio frequency power source coupled to the first electrode and applying a voltage thereto for converting the process gas into a plasma having charged particles and activated neutral species, the first radio frequency power source operating at a frequency that is greater than 13.56 MHz, generation of the plasma causing a self biasing of the first electrode, the self biasing being reduced by operating at the increased frequency of the first radio frequency power source; an induction coil adjacent to at least a portion of the vacuum chamber, the induction coil operatively coupled to a second pulsable radio frequency power source to inductively couple power into the vacuum chamber to produce at least one plasma; wherein the pulsable radio frequency power source is cycled between a high power and a low power at a selected duty cycle.

It is also an object of this invention to provide a method for etching a semiconductor substrate comprising placing the semiconductor substrate on a first electrode in a vacuum chamber; providing a process gas to the vacuum chamber; introducing a radio frequency power coupled to the first electrode at a frequency greater than 13.56 MHz into the vacuum chamber to produce a plasma from the process gas, generation of the plasma causing a self biasing of the first electrode, the self biasing being reduced by operating at the increased frequency of the radio frequency power source; pulsing the radio frequency power source between a high power and a low power at a selected duty cycle; and exposing the semiconductor substrate to the plasma.

It is also an object of this invention to provide a method for etching a semiconductor substrate comprising placing the semiconductor substrate on a first electrode in a vacuum chamber; providing a process gas to the vacuum chamber; introducing a radio frequency power coupled to the first electrode at a frequency greater than 13.56 MHz into the vacuum chamber to produce a plasma from the process gas, generation of the plasma causing a self biasing of the first electrode, the self biasing being reduced by operating at the increased frequency of the radio frequency power source; and exposing the semiconductor substrate to the plasma.

It is also an object of this invention to provide a method for etching a semiconductor substrate comprising placing the semiconductor substrate on a first electrode in a vacuum chamber; providing a process gas to the vacuum chamber; introducing a radio frequency power coupled to the first electrode at a frequency of 13.56 MHz into the vacuum chamber to produce a plasma from the process gas; introducing a pulsed radio frequency power source into the vacuum chamber, the pulsed radio frequency power source being cycled between a high power and a low power at a selected duty cycle; and exposing the semiconductor substrate to the plasma.

It is also an object of this invention to provide a method for etching a semiconductor substrate comprising placing the semiconductor substrate on a first electrode in a vacuum chamber; providing a process gas to the vacuum chamber; introducing a first radio frequency power coupled to the first electrode at a frequency greater than 13.56 MHz into the vacuum chamber to produce a plasma from the process gas, generation of the plasma causing a self biasing of the first electrode, the self biasing being reduced by operating at the increased frequency of the first radio frequency power source; introducing a second radio frequency power coupled to an induction coil adjacent to at least a portion of the vacuum chamber to produce at least one plasma; pulsing the second radio frequency power source such that the power to the induction coil alternates between a high power and a low power at a selected duty cycle; and exposing the semiconductor substrate to the plasma.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a fuller understanding of the nature and objects of the invention, reference should be had to the following detailed description taken in connection with the accompanying drawings in which:

FIG. 1 is a graph plotting plasma DC bias versus RF power at multiple frequencies for the system of the present invention;

FIG. 2 is a schematic view of the reactive ion etch plasma etching system of the present invention;

FIG. 3 is a graph of GaAs etch rate versus RF duty cycle for the system of the present invention;

FIG. 4 is a schematic view of the inductively coupled plasma etching system of the present invention;

FIG. 5 is a contour plot of GaAs etch rate versus RF power and RF duty cycle for the system of the present invention; and

FIG. 6 is a graph plotting etch depth of epitaxial GaAs and AlGaAs versus etching time for the system of the present invention.

Similar reference characters refer to similar parts throughout the several views of the drawings.

### DETAILED DESCRIPTION OF THE PREFERRED EMBODIMENT

The present invention relates to an apparatus and method for etching thin damage sensitive layers with a plasma. The invention finds particular application to etching damage sensitive thin films, such as a layer(s) of Gallium Arsenide (GaAs) on a layer(s) of Aluminum Gallium Arsenide (AlGaAs) on a Gallium Arsenide substrate. Nonetheless, the principles of the present invention find application on various semiconductor structures, e.g., etching thin films of silicon nitride on GaAs or the etching of Indium containing thin films as well.

Previous studies have shown that etch induced damage is primarily caused by high energy ion bombardment of the substrate which is a function of the plasma potential and self-induced DC bias voltage (V_{dc}). A number of groups have reported that maintaining |Vdc|<50 V results in minimal plasma etch process induced damage. Thus, damage to sensitive thin films is avoided by lowering the DC bias of the cathode. The low DC bias is made possible by increasing the frequency of the power source that produces the plasma. It is known that the DC Bias is inversely related to the frequency of the radio frequency (RF) power source. Therefore, a high frequency results in a lower DC Bias.

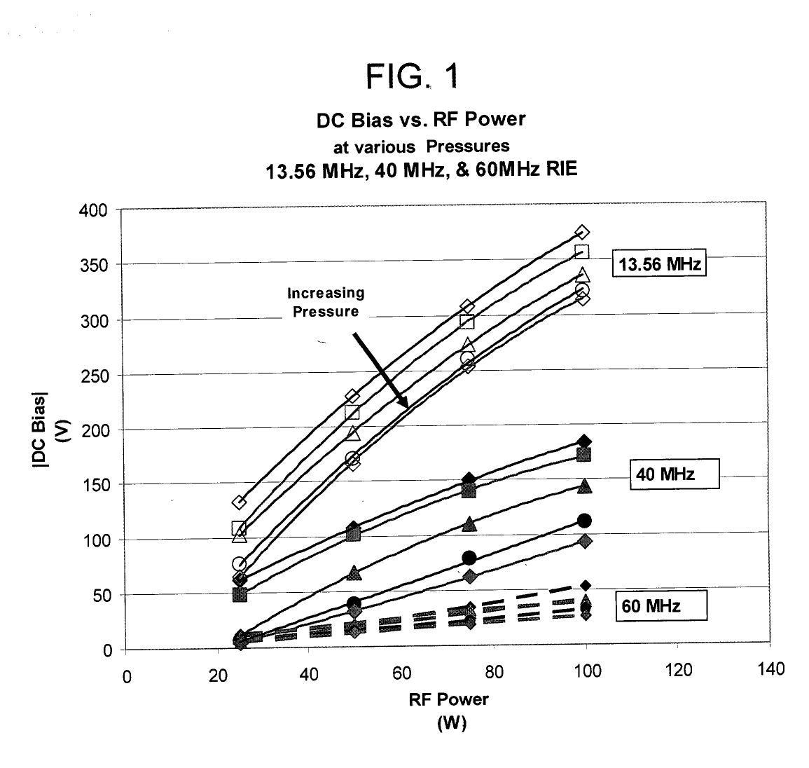

FIG. 1 illustrates that, at a constant power, increasing the frequency of the power supply from 13.56 Mhz to 40.68 Mhz results in a reduction of DC bias. The graph likewise illustrates that increasing pressure while maintaining a constant power also reduces DC bias. However, at high pressures, the etch rate increases, the etch becomes more isotropic and the uniformity decreases.

While the increased frequency lowers the DC bias (and consequently ion energy at the wafer surface) the etch rate of GaAs using a BCl₃/SF₆ process is relatively independent of RF frequency. The etching of GaAs in a chlorine based chemistry is primarily chemically driven as opposed to an ion driven mechanism. Consistent with the results of previous groups investigating BCl₃/SF₆ chemistries in a 13.56 MHz RIE configuration, the 40.68 MHz GaAs etch rate was 1200 Å/min.

In order to realize a reproducible manufacturing process, it is desirable to have process times of at least one minute in length. For example, etching a 300 Å thick GaAs film at 1200 Å/min suggests an etch time of approximately 15 seconds, resulting in a process with poor reproducibility. Slowing the etch rate by simply reducing RF power levels is generally impractical since plasma stability and reproducibility become major concerns. In order to slow the GaAs etch rate for thin film applications, the 40.68 MHz RF power was alternated between a high power and low power state over time. It is important to note that the applied voltage to the substrate is |V_{dc}|<50 V during both the high power and low power periods.

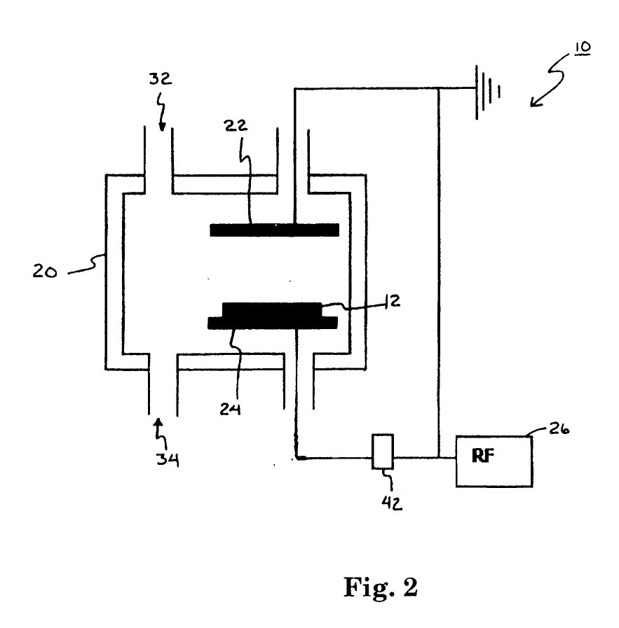

With reference now to FIG. 2, a modified Reactive Ion Etch (RIE) system 10 of the present invention is disclosed. This system 10 includes a vacuum chamber 20 that houses a pair of spaced electrodes. The upper electrode 22 is grounded and serves as an anode. In some systems, the vacuum chamber 20 can be the anode. The lower electrode 24 is coupled to a pulsable RF power source 26 and serves as the cathode. The cathode 24 supports the substrate 12 to be processed.

The chamber 20 additionally includes an inlet 32 to permit the ingress of a process gas and an outlet 34 for exhausting the process gas after etching processes have occurred. Suitable process gases for selectively etching GaAs relative to AlGaAs include BCl₃ and SF₆. The system additionally includes a matching network 42 in a manner known in the art.

In use, the RF voltage is applied to the lower electrode (cathode) 24 by way of the matching network 42. Application of the voltage produces a plasma in the vacuum chamber. Creation of the plasma causes the creation of electrons, positive and negative ions, and neutral radicals. The negative voltage formed at the cathode causes positive ions to bombard the substrate 12. While at the same time, the radicals from the plasma chemically etch the exposed surfaces of the thin films (GaAs) on the substrate 12.

Most RIE systems employ a power source operating at a radio frequency of 13.56 MHz. By contrast, the present invention contemplates using a radio frequency greater than 13.56 MHz. An increase to 40.68 MHz reduces the self-induced DC bias by a factor of 3. Higher frequencies can also be used. For example, increasing the frequency to 60 MHz reduces the self-induced DC bias by a factor of 4.4.

It is important to note that a threshold DC bias is needed to promote an anisotropic etch. Consequently, while reducing the DC bias is effective in reducing damage to sensitive layers, a balance must be achieved between the desire for anisotropic etching and the need to minimize damage.

In order to effectively etch thin films (less than 1000 Angstroms thick), the RIE reactor 10 can also provide a reduced etch rate. This is achieved by making the RF power source 26 pulsable. Reduced etch rates are achieved by pulsing the RF power source 26 between a high power and a low power for a selected duty cycle. The duty cycle represents the percentage of time that the RF power is at a high power relative to the total time the RF power is on. Duty Cycle=(Time of RF_{high})/(Time of RF_{high}+Time of RF_{low}). The RF on-time is in the range of 10 μs to 1 second. The preferred RF on-time is in the range of 0.5 ms to 10 ms. The pulsable RF power source 26 allows the duty cycle to be selected. By reducing the duty cycle, the etch rate of the plasma can be reduced. For example, a typical etch rate of 2000 Angstroms per minute can be reduced to 1000 Angstroms per minute by operating at a 50 percent duty cycle. Here, the RF_{low} is selected so that it results in minimal etching. The desired duty cycle should be <50%, preferably 5-30%.

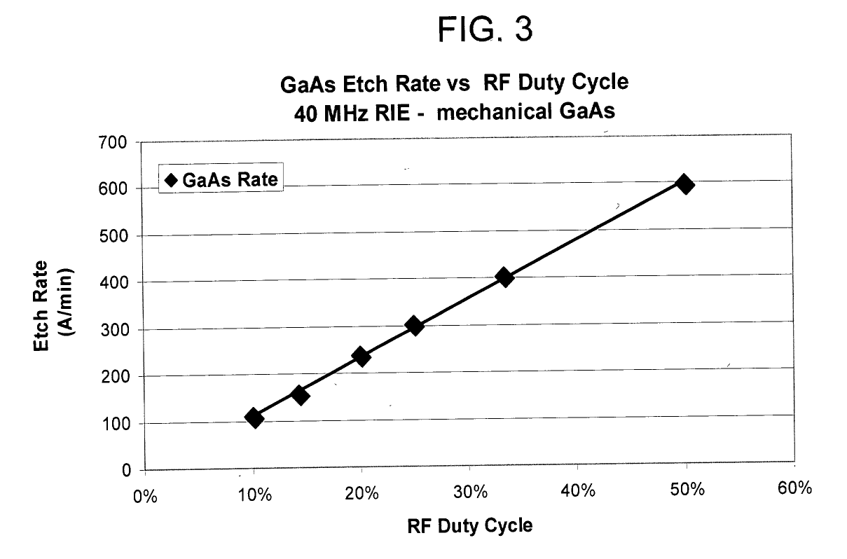

FIG. 3 shows the relationship between duty cycle (ratio of high power time to total cycle time) and GaAs etch rate for a BCl₃/SF₆ process. The graph demonstrates that as duty cycle is decreased, there is a corresponding reduction in etch rate. Using a 25% duty cycle at a frequency of 40.68 MHz with an RF_{high} of 45 W and an RF_{low} of 0 W at an RF high time of 1 ms resulted in GaAs etch rates near 300 Å/min yielding a one minute process time for a 300 Å thick film of GaAs.

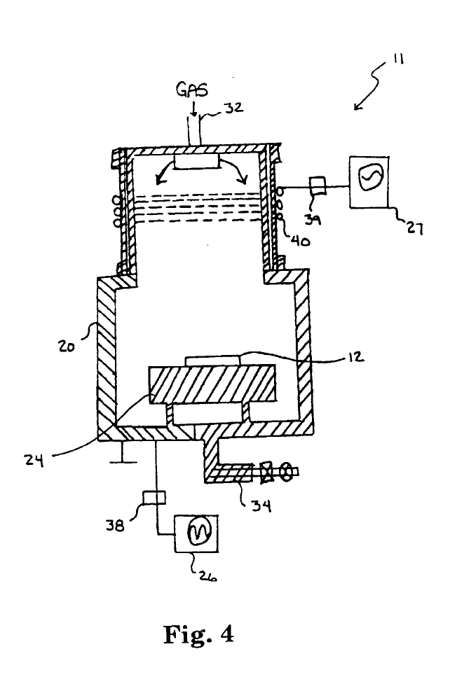

With reference now to FIG. 4, the principles of the present invention are illustrated in a modified Inductively Coupled Plasma (ICP) system 11. This system 11 is similar to the RIE system described herein and includes a vacuum chamber 20 that houses an electrode 24. The vacuum chamber 20 is typically grounded and serves as a second electrode. The lower electrode 24, which serves as the cathode, is coupled to a first RF power source 26. The cathode 24 supports the substrate 12 to be processed. The first power source 26 is operatively connected to a first matching network 38 in a manner known in the art.

The chamber 20 additionally includes an inlet 32 to permit the ingress of a process gas and an outlet 34 for exhausting the process gas after etching processes have occurred.

A second pulsable RF power source 27 is operatively connected to a second matching network 39 in a manner known in the art. The second RF power source 27 is operatively connected to at least one coil or loop 40 that is adjacent to at least a portion of the chamber 20. The coil or loop 40 inductively couples power into the vacuum chamber 20 to produce at least one plasma.

Creation of the plasma by both the first RF power source 26 and the second RF power source 27 causes the creation of electrons, positive and negative ions, and neutral radicals. The negative voltage formed at the cathode causes positive ions to bombard the substrate 12 whereby physical etching occurs to the exposed surfaces of the thin films (GaAs) on the substrate 12. While at the same time, the radicals from the plasma chemically etch the exposed surfaces of the thin films (GaAs) on the substrate 12.

Most ICP systems employ a first RF power source 26 operating at a radio frequency of 13.56 MHz. By contrast, the RF power source 26 of the present invention contemplates using a radio frequency greater than 13.56 MHz. Higher RF bias frequency will result in a lower DC bias (V_{dc}). Note, the frequency of the second RF power source 27 is primarily relevant to the density of the plasma created. Whereas, the ion bombardment of the substrate is controlled by the RF bias of the substrate, i.e., frequency of the first source.

High frequency RF bias is particularly useful in reducing damage in the case where the high density source is pulsed between some high power and a low power of zero. For this case, during the period where the high density plasma is extinguished, the reactor behaves similarly to a parallel plate configuration. Using a high frequency RF bias, the DC bias can be held below 50 V even in the absence of the high density plasma. It is important to note that a threshold DC bias is needed to promote an anisotropic etch. Consequently, while reducing the DC bias is effective in reducing damage to sensitive layers, a balance must be achieved between the desire for anisotropic etching and the need to minimize damage.

In addition, in order to effectively etch thin films (less than 1000 Angstroms thick), the present invention is also directed to a system for providing a reduced etch rate. Reduced etch rates are achieved by pulsing the second RF power source 27 between a high power and a low power for a selected duty cycle. The second RF power source 27 is pulsable such that a duty cycle can be selected. By reducing the duty cycle, the etch rate of the plasma can be reduced. The desired duty cycle should be <50%, preferably 5-30%. In an additional embodiment, both the first and second RF power sources (26 and 27, respectively) are pulsable.

As a result, a reduced etch rate, suitable for etching thin layers (10-1000 Angstroms thick) is achieved by pulsing the power source between a high power and a low power at a selected duty cycle. In one alternative embodiment, the power source is pulsed by switching it on and off for a selected duty cycle. The principles of the present invention find application in both an inductively coupled plasma reactor and a reactive ion etch reactor.

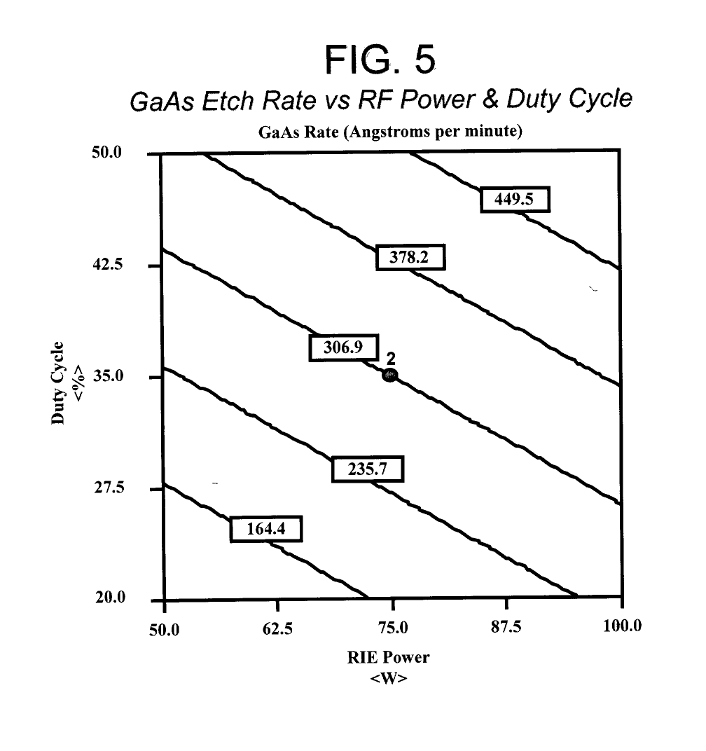

The contour plot of FIG. 5 illustrates the GaAs etch rate as a function of Duty Cycle and RIE power. As expected, the etch rate decreases with reduced RIE power and Duty Cycle.

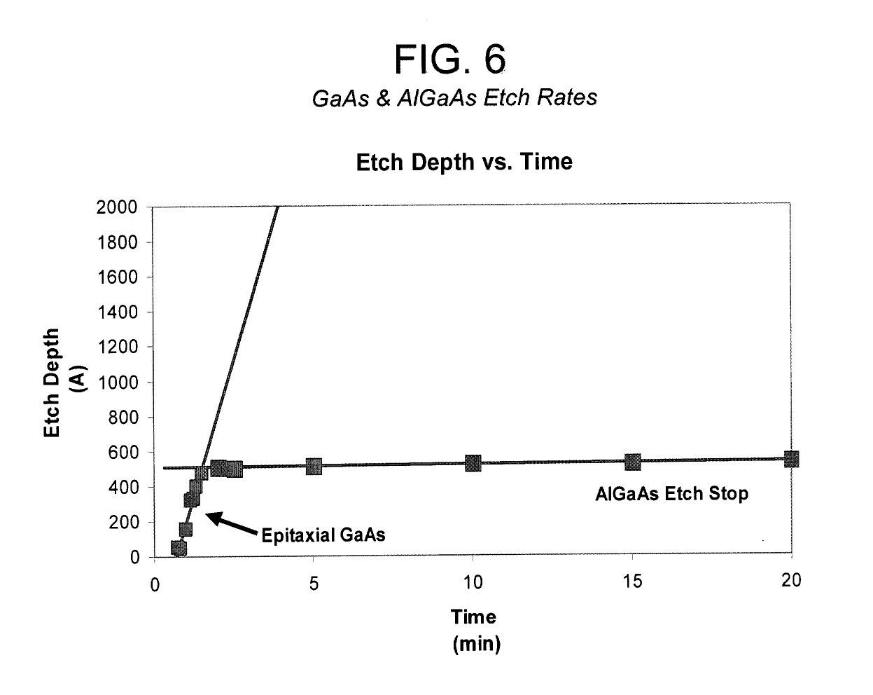

In addition to having low damage and a controllable etch rate, the GaAs etch process for many devices must be highly selective to an AlGaAs etch stop. In order to determine the GaAs and AlGaAs etch rates, a number of samples were etched using an identical process for times ranging from 10 seconds to 20 minutes. FIG. 6 shows the relationship between etch depth and time for etching GaAs on an AlGaAs layer. Based on the GaAs and AlGaAs etch rates, the GaAs:AlGaAs etch selectivity is approximately 399:1.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

Now that the invention has been described,

What is claimed is:

1. A plasma reactor for processing a substrate comprising:
a vacuum chamber;
a first electrode for supporting the substrate within said vacuum chamber;
a second electrode being grounded;
a process gas;
a pulsable radio frequency power source electrically coupled to the first electrode and applying a voltage thereto for converting the process gas into a plasma having charged particles and activated neutral species, the pulsable radio frequency power source operating at a frequency that is greater than 13.56 MHz, generation of the plasma causing a self biasing of the first electrode, the self biasing being reduced by operating at the increased frequency of the radio frequency power source; and
wherein the pulsable radio frequency power source is cycled between a high power and a low power at a selected duty cycle.

2. The system as described in claim 1 wherein the duty cycle is less than 50%.

3. The system as described in claim 1 wherein the duty cycle is between 5-30%.

4. The system as described in claim 1 wherein the pulsable radio frequency power source is pulsed on and off at a selected duty cycle.

5. The system as described in claim 4 wherein the duty cycle is less than 50%.

6. The system as described in claim 4 wherein the duty cycle is between 5-30%.

7. The system as described in claim 1 wherein the frequency of the radio frequency power source is selected such that the self biasing of the first electrode |V_{dc}| is less than 50 volts.

8. The system as described in claim 1 wherein the frequency of the radio frequency power source is 40.68 MHz.

9. A plasma reactor for processing a substrate comprising:
a vacuum chamber;
a first electrode for supporting the substrate within said vacuum chamber;
a second electrode being grounded;
a process gas; and
a radio frequency power source coupled to the first electrode and applying a voltage thereto for converting the process gas into a plasma having charged particles and activated neutral species, the radio frequency power source operating at a frequency that is greater than 13.56 MHz, generation of the plasma causing a self biasing of the first electrode, the self biasing being reduced by operating at the increased frequency of the power source.

10. The system as described in claim 9 wherein the power source is a radio frequency power source operating at 40.68 Mhz.

11. The system as described in claim 9 wherein the frequency is selected to produce a DC bias |V_{dc}| of less than 50 volts.

12. A plasma reactor for processing a substrate comprising:
a vacuum chamber;
a first electrode for supporting the substrate within said vacuum chamber;
a second electrode being grounded;
a process gas;
a pulsable radio frequency power source coupled to the first electrode and applying a voltage thereto for converting the process gas into a plasma having charged particles and activated neutral species, the radio frequency power source operating at a frequency of 13.56 MHz; and
wherein the pulsable radio frequency power source is cycled between a high power and a low power at a selected duty cycle.

13. The system as described in claim 12 wherein the duty cycle is less than 50%.

14. The system as described in claim 12 wherein the duty cycle is between 5-30%.

15. The system as described in claim 12 wherein the pulsable radio frequency power source is pulsed on and off at a selected duty cycle.

16. The system as described in claim 15 wherein the duty cycle is less than 50%.

17. The system as described in claim 15 wherein the duty cycle is between 5-30%.

18. A plasma reactor for processing a substrate comprising:
a vacuum chamber;
a first electrode for supporting the substrate within said vacuum chamber;
a second electrode being grounded;
a process gas;
a first radio frequency power source coupled to the first electrode and applying a voltage thereto for converting the process gas into a plasma having charged particles and activated neutral species, the first radio frequency power source operating at a frequency that is greater than 13.56 Mhz, generation of the plasma causing a self biasing of the first electrode, the self biasing being reduced by operating at the increased frequency of the first radio frequency power source;
an induction coil adjacent to at least a portion of the vacuum chamber, the induction coil operatively coupled to a pulsable radio frequency power source to inductively couple power into the vacuum chamber to produce at least one plasma; and
wherein the pulsable radio frequency power source is cycled between a high power and a low power at a selected duty cycle.

19. The system as described in claim 18 wherein the duty cycle is less than 50%.

20. The system as described in claim 18 wherein the duty cycle is between 5-30%.

21. The system as described in claim 18 wherein the pulsable radio frequency power source is pulsed on and off at a selected duty cycle.

22. The system as described in claim 21 wherein the duty cycle is less than 50%.

23. The system as described in claim 21 wherein the duty cycle is between 5-30%.

24. The system as described in claim 18 wherein the self biasing of the first electrode |V_{dc}| is less than 50 volts.

25. The system as described in claim 18 wherein the radio frequency of the first radio frequency power source is 40.68 MHz.

26. A method for etching a semiconductor substrate comprising:
placing the semiconductor substrate on a first electrode in a vacuum chamber;
providing a process gas to the vacuum chamber;
introducing a radio frequency power coupled to the first electrode at a frequency greater than 13.56 MHz into the vacuum chamber to produce a plasma from the process gas, generation of the plasma causing a self biasing of the first electrode, the self biasing being reduced by operating at the increased frequency of the radio frequency power source;
pulsing the radio frequency power source between a high power and a low power at a selected duty cycle; and
exposing the semiconductor substrate to the plasma.

27. The method as described in claim 26 wherein the duty cycle is less than 50%.

28. The method as described in claim 26 wherein the duty cycle is between 5-30%.

29. The method as described in claim 26 wherein the pulsable radio frequency power source is pulsed on and off at a selected duty cycle.

30. The method as described in claim 26 wherein the duty cycle is less than 50%.

31. The method as described in claim 29 wherein the duty cycle is between 5-30%.

32. The method as described in claim 29 wherein the frequency is selected to produce a DC bias |V_{dc}| of less than 50 volts.

33. The method as described in claim 26 wherein the radio frequency of the power source is 40.68 MHz.

34. The method as described in claim 26 wherein the substrate further comprises at least one indium containing layer.

35. The method as described in claim 26 wherein the substrate further comprises at least one gallium containing layer.

36. The method as described in claim 35 wherein the substrate further comprises at least one aluminum containing layer.

37. A method for etching a semiconductor substrate comprising:
placing the semiconductor substrate on a first electrode in a vacuum chamber;
providing a process gas to the vacuum chamber;
introducing a radio frequency power coupled to the first electrode at a frequency greater than 13.56 MHz into the vacuum chamber to produce a plasma from the process gas, generation of the plasma causing a self biasing of the first electrode, the self biasing being reduced by operating at the increased frequency of the radio frequency power source; and
exposing the semiconductor substrate to the plasma.

38. The method as described in claim 37 wherein the radio frequency of the power source is 40.68 MHz.

39. The method as described in claim 37 wherein the frequency is selected to produce a DC bias |V_{dc}| of less than 50 volts.

40. The method as described in claim 37 wherein the substrate further comprises at least one indium containing layer.

41. The method as described in claim 37 wherein the substrate further comprises at least one gallium containing layer.

42. The method as described in claim 41 wherein the substrate further comprises at least one aluminum containing layer.

43. A method for etching a semiconductor substrate comprising:
placing the semiconductor substrate on a first electrode in a vacuum chamber;
providing a process gas to the vacuum chamber;
introducing a radio frequency power coupled to the first electrode at a frequency of 13.56 MHz into the vacuum chamber to produce a plasma from the process gas;
introducing a pulsed radio frequency power source into the vacuum chamber, the pulsed radio frequency power source being cycled between a high power and a low power at a selected duty cycle; and
exposing the semiconductor substrate to the plasma.

44. The method as described in claim 43 wherein the duty cycle is less than 50%.

45. The method as described in claim 43 wherein the duty cycle is between 5-30%.

46. The method as described in claim 43 wherein the pulsable radio frequency power source is pulsed on and off at a selected duty cycle.

47. The method as described in claim 46 wherein the duty cycle is less than 50%.

48. The method as described in claim 46 wherein the duty cycle is between 5-30%.

49. The method as described in claim 43 wherein the substrate further comprises at least one indium containing layer.

50. The method as described in claim 43 wherein the substrate further comprises at least one gallium containing layer.

51. The method as described in claim 50 wherein the substrate further comprises at least one aluminum containing layer.

52. A method for etching a semiconductor substrate comprising:
placing the semiconductor substrate on a first electrode in a vacuum chamber;
providing a process gas to the vacuum chamber;
introducing a first radio frequency power coupled to the first electrode at a frequency greater than 13.56 MHz into the vacuum chamber to produce a plasma from the process gas, generation of the plasma causing a self biasing of the first electrode, the self biasing being reduced by operating at the increased frequency of the first radio frequency power source;
introducing a second radio frequency power coupled to an induction coil adjacent to at least a portion of the vacuum chamber to produce at least one plasma;
pulsing the second radio frequency power source such that the power to the induction coil alternates between a high power and a low power at a selected duty cycle; and
exposing the semiconductor substrate to the plasma.

53. The method as described in claim 52 wherein the duty cycle is less than 50%.

54. The method as described in claim 52 wherein the duty cycle is between 5-30%.

55. The method as described in claim 52 wherein the pulsable radio frequency power source is pulsed on and off at a selected duty cycle.

56. The method as described in claim 55 wherein the duty cycle is less than 50%.

57. The method as described in claim 55 wherein the duty cycle is between 5-30%.

58. The method as described in claim 52 wherein the frequency of the first radio frequency power source is selected to produce a DC bias |Vdc| of less than 50 volts.

59. The method as described in claim 52 wherein the radio frequency of the first radio frequency power source is 40.68 MHz.

60. The method as described in claim 52 wherein the substrate further comprises at least one indium containing layer.

61. The method as described in claim 52 wherein the substrate further comprises at least one gallium containing layer.

62. The method as described in claim 61 wherein the substrate further comprises at least one aluminum containing layer.
